(19) United States
(12) Patent Application Publication
(10) Pub. No.: US 2025/0003055 A1
(43) Pub. Date: Jan. 2, 2025

(54) THIN FILM DEPOSITION APPARATUS AND DEPOSITION METHOD

(71) Applicant: SEMICONDUCTOR INTEGRATED DISPLAY TECHNOLOGY CO., LTD., Wuhu (CN)

(72) Inventors: Chengyuan LIU, Wuhu (CN); Luyang FENG, Wuhu (CN); Jinting WEI, Wuhu (CN); Wenlian LI, Wuhu (CN)

(21) Appl. No.: 18/752,166

(22) Filed: Jun. 24, 2024

(30) Foreign Application Priority Data
Jun. 29, 2023 (CN) 202310784588.3

(51) Int. Cl. C23C 14/28; C23C 14/26

(52) U.S. Cl. CPC C23C 14/28; C23C 14/26

(57) ABSTRACT

A thin film deposition apparatus and thin film deposition method are disclosed. The thin film deposition apparatus includes a plurality of evaporation sources at a bottom of a film deposition chamber of the thin film deposition apparatus; a plurality of beam splitters in a middle of the film deposition chamber, where each beam splitter comprises a frame and a plurality of beam splitter components arranged at intervals on the frame, and each beam splitter component comprises a plurality of reflecting surfaces connected in series; and a plurality of plane reflectors corresponding one-to-one to the plurality of beam splitters, where each plane reflector is located at a side of a corresponding beam splitter inside the film deposition chamber.

### CROSS-REFERENCE TO RELATED APPLICATIONS

This application claims priority to Chinese Patent Application No. 202310784588.3, filed with the China National Intellectual Property Administration on Jun. 29, 2023, which is hereby incorporated by reference in its entirety.

### TECHNICAL FIELD

The disclosure relates to the field of semiconductor product manufacturing technology, and in particularly, relates to a thin film deposition apparatus, and a thin film deposition method.

### BACKGROUND

In vapor deposition technologies such as vacuum thermal evaporation and molecular beam epitaxy, in order to make the prepared materials or devices have higher uniformity and more delicate structures, higher requirements on directions for the gas phase materials or material particles or others emitted from a material source (such as an evaporation source) during the thin film deposition process are necessary.

### SUMMARY

The disclosure provides a thin film deposition apparatus, where a plurality of evaporation sources are arranged at a lower part of a film coating chamber wall of the thin film deposition apparatus, a corresponding curved reflector is arranged at a position of each evaporation source, a plane reflector is further arranged at the lower part of the film coating chamber wall, a beam splitter is arranged in a middle part of the film coating chamber wall, the beam splitter includes a plurality of beam splitter components, each beam splitter component is set to be arranged at an acute angle with a horizontal direction, a plane reflector is further arranged at a side surface of the beam splitter, the plane reflector is set to be arranged at an acute angle with the horizontal direction, and a substrate is arranged at an upper part of the film coating chamber wall. The plane reflector, the curved reflector and the beam splitter component are each provided with a heating component.

The disclosure further provides a thin film deposition method, which has simple steps and low cost, is convenient and reliable to use, ensures that the vapor material or material particles emitted from the material source have high directionality during the thin film deposition process, converts the point source or line source in the device in various vapor deposition technologies such as vacuum thermal evaporation and molecular beam epitaxy into a surface source, eliminates the shadow effect, improves the uniformity of thin film deposition, and ultimately improves the product performance. The thin film deposition method includes:
S1: emitting, by each evaporation source, material beams via a nozzle, where each material beam is emitted to a corresponding curved reflector and is reflected to a corresponding plane reflector, each plane reflector then sprays the corresponding material beam to a surface of a corresponding beam splitter component of a beam splitter;
S2: based on that material beams propagating in a vertical direction are sprayed to surfaces of corresponding beam splitter components of the beam splitter, reflecting a part (about one half) of the material beams onto a base on the film coating chamber wall in a horizontal direction, and continuing to propagate a part (about the other half) of the material beams after being reflected in the vertical direction;
S3: based on that material beams propagating in the horizontal direction are sprayed to surfaces of corresponding beam splitter components of the beam splitter, reflecting all the material beams to propagate in the vertical direction;
S4: causing the material beams propagating in the vertical direction and the horizontal direction to form mixed vertical material beams after being reflected by the beam splitter, to enter the uppermost beam splitter (components); and
S5: coating or doping material beams emitted from different evaporation sources on the substrate at a same small angle after passing through the uppermost beam splitter, where deposition is completed after coating or doping.

The disclosure further provides a thin film deposition apparatus, including: a plurality of evaporation sources at a bottom of a film deposition chamber of the thin film deposition apparatus; a plurality of beam splitters in a middle of the film deposition chamber, where each beam splitter comprises a frame and a plurality of beam splitter components arranged at intervals on the frame, and each beam splitter component comprises a plurality of reflecting surfaces connected in series; and a plurality of plane reflectors corresponding one-to-one to the plurality of beam splitters, where each plane reflector is located at a side of a corresponding beam splitter inside the film deposition chamber.

In some embodiments, the reflecting surface is flat or curved.

In some embodiments, any two adjacent reflecting surfaces among the plurality of reflecting surfaces connected in series are angled.

In some embodiments, the beam splitter component has a square prism structure.

In some embodiments, the thin film deposition apparatus further includes a plurality of curved reflectors, corresponding one-to-one to the plurality of evaporation sources, at the bottom of the film deposition chamber. The plurality of curved reflectors correspond one-to-one to the plurality of plane reflectors respectively, and each curved reflector is configured to reflect a material beam from a corresponding evaporation source onto a corresponding plane reflector.

In some embodiments, each evaporation source includes at least one nozzle, and the at least one nozzle faces a curved reflector corresponding to the evaporation source.

In some embodiments, each plane reflector is rectangular in shape, and each curved reflector is paraboloid of revolution or trough paraboloid in shape.

In some embodiments, each evaporation source is a point source, and the frame of the beam splitter is oval in shape.

In some embodiments, each evaporation source is a line source, and the frame of the beam splitter is rectangular in shape.

In some embodiments, a surface material of the curved reflector is stainless steel, Al₂O₃, single crystal silicon, or diamond coating film. A surface material of the plane reflector is stainless steel, Al₂O₃, single crystal silicon, or diamond coating film.

In some embodiments, the plane reflector includes a heating component inside the plane reflector. The beam splitter component includes a heating component inside the beam splitter component. The curved reflector includes a heating component inside the curved reflector.

In some embodiments, the heating component is a resistance wire.

In some embodiments, the plane reflector includes a heating component inside the plane reflector. The beam splitter component includes a heating component inside the beam splitter component.

In some embodiments, the heating component is a resistance wire.

In some embodiments, a surface material of the plane reflector is stainless steel, Al₂O₃, single crystal silicon, or diamond coating film.

In some embodiments, in each beam splitter, each beam splitter component includes a reflecting surface parallel to a plane reflector corresponding to the beam splitter.

In some embodiments, each evaporation source is a molecular beam source.

In some embodiments, the plurality of beam splitters are arranged along a direction perpendicular to a bottom wall of the film deposition chamber.

The disclosure further provides a method for using the thin film deposition apparatus according to the above embodiments, including:
emitting, by at least one evaporation source, a material beam, to enable the material beam to reach a plane reflector corresponding to the at least one evaporation source;
reflecting, by the plane reflector, the material beam to a beam splitter corresponding to the plane reflector; and
forming, by the plurality of beam splitters, the material beam from the at least one evaporation source as a planar material beam, to enable the planar material beam to reach a substrate at a top of the film deposition chamber.

In some embodiments, each evaporation source is correspondingly provided with a curved reflector, one curved reflector corresponds to one plane reflector and one beam splitter; and among the plurality of evaporation sources, an evaporation source corresponding to a beam splitter closest to the substrate is indicated as a first evaporation source, and remaining evaporation sources are indicated as second evaporation sources. The method includes:
S1, each second evaporation source emitting a material beam to a curved reflector corresponding to the second evaporation source, the curved reflector reflecting the material beam to a plane reflector corresponding to the curved reflector, and the plane reflector reflecting the material beam to corresponding reflecting surfaces of a plurality of beam splitter components of a beam splitter corresponding to the curved reflector;
S2, when a material beam propagating in a vertical direction reaches corresponding reflecting surfaces of a plurality of beam splitter components of a beam splitter corresponding to the curved reflector, a part of the material beam being reflected to a base on a wall of the film deposition chamber in a horizontal direction, and a part of the material beam being reflected by other reflecting surfaces for further propagation in the vertical direction;
S3, when a material beam propagating in the horizontal direction reaches corresponding reflecting surfaces of a plurality of beam splitter components of a beam splitter corresponding to the curved reflector, the material beam being totally reflected for further propagation in the vertical direction;
S4, the material beam for further propagation in the vertical direction in part or totally propagating to a next beam splitter until reaching corresponding reflecting surfaces of a plurality of beam splitter components of the beam splitter closest to substrate, a portion of the material beam being reflected to a base on the wall of the film deposition chamber in the horizontal direction, and a portion of the material beam being reflected by other reflecting surfaces for further propagation in the vertical direction until reaching the substrate;
S5, the first evaporation source emitting a material beam to a curved reflector corresponding to the first evaporation source, the curved reflector reflecting the material beam to a plane reflector corresponding to the curved reflector, the plane reflector reflecting the material beam in the horizontal direction onto corresponding reflecting surfaces of the plurality of beam splitter components of the beam splitter closest to the substrate, and the material beam being reflected to propagate in the vertical direction to reach the substrate.

### BRIEF DESCRIPTION OF FIGURES

The content indicated in the drawings attached to this specification and the reference signs in the drawings will be briefly illustrated below.

FIG. 1A is a schematic a side-view of a thin film deposition apparatus according to the disclosure.

FIG. 1B is a schematic top-view of a thin film deposition apparatus when evaporation sources are point sources.

FIG. 1C is a perspective schematic diagram of a thin film deposition apparatus when evaporation sources are line sources, viewed from a 45° downward angle.

FIG. 1D is a schematic side-view of a molecular beam epitaxy thin film deposition apparatus.

FIG. 2A is a structural schematic diagram of a plane reflector.

FIG. 2B is a structural schematic diagram of a curved reflector.

FIG. 3A is a schematic side-view of a beam splitter corresponding to a point source.

FIG. 3B is a schematic top-view of a beam splitter corresponding to a point source.

FIG. 4A illustrates a principle of the beam splitter reflecting material beams in a horizontal direction.

FIG. 4B illustrates a principle of the beam splitter reflecting material beams in a vertical direction.

FIG. 4C illustrates a working principle of the thin film deposition apparatus.

FIG. 5 shows schematic diagrams of optional cross-sectional shapes of beam splitter components of the beam splitter.

The reference signs in the accompanying drawings are:

10. film deposition chamber wall; 11. substrate; 12. mask plate; 13. heating component; 14. reflecting surface; 20. evaporation source; 21. nozzle; 30. curved reflector; 40. plane reflector; 50. beam splitter; 51. frame of beam splitter; 52. beam splitter component; 60. molecular beam epitaxy device; 61. molecular beam emission slit; 62. liquid nitrogen cooling shield; 63. source furnace flange; 70. material beam.

### DETAILED DESCRIPTION

The specific implementations of the disclosure, such as the shapes and structures of various components, the mutual positions and connection relationships among various parts, the functions and working principles of various parts, etc., involved in the disclosure, will be illustrated below in details through the description of the embodiments with reference to the accompanying drawings.

At present, the material sources used in vacuum film coating technologies such as vacuum thermal evaporation and molecular beam epitaxy are mostly point sources or line sources. The material beams emitted from these material sources often have different incident angles relative to the normal of a substrate, resulting in the shadow effect and non-uniformity of the film deposition. In vacuum vapor deposition technologies such as vacuum thermal evaporation and molecular beam epitaxy, a point source or line source emits a vapor material beam (atomic beam, ion beam, molecular beam or any other form of material beam, etc.) in an approximately straight line and flies in a vacuum cavity. When the vapor material beam encounters a cavity wall base, condensation wall, mask plate, substrate or other device surface, the adsorption, secondary evaporation or reflection will occur. The incident angle is defined as an angle between the velocity direction of the atomic beam, molecular beam or material particle when striking the substrate and the normal of the substrate. The incident angle is generally between 0 and 90°. The smaller the incident angle, the better the quality and uniformity of the thin film deposition, and the smaller the effective size of the fine structure of the thin film device. In view of this, the surface source technology has received a certain amount of attention and has been extensively studied. The surface source refers to a film coating source with a planar structure. Compared with a point or line source, the atomic beams, molecular beams or material particles emitted from the surface source can be incident onto the substrate vertically, so the incident angle thereof is 0°. At present, in the method based on the surface source in the field of vacuum thermal evaporation, generally the materials of the point source or line source are vapourized together onto an intermediate substrate with a lower temperature, and then the intermediate substrate is directed to a final substrate and is heated, so that the entire material film on the intermediate substrate is vapourized onto the final substrate. These surface source technologies have many difficulties and are inefficient and costly, making them difficult to promote in a short period of time.

In the related art, a thin film deposition equipment includes a thin film deposition chamber, including: a housing enclosing a cavity of the thin film deposition chamber; a target bracket arranged in the middle of the cavity and used to place the target consisting of component A; a substrate platform arranged in the middle of the cavity and arranged opposite to the target bracket; a laser incident port arranged at the side of the housing and obliquely opposite to the target bracket, and used for incidence of the laser to bombard the target on the target bracket to generate plasma plume; and a beam source furnace interface arranged at the side of the housing and obliquely opposite to the substrate platform, and used for incidence of a molecular beam stream consisting of component B; where the laser incident port and the beam source furnace interface simultaneously provide the incident laser and molecular beam stream.

The disclosure provides a thin film deposition apparatus, which has a simple structure and low cost, is convenient and reliable to use, and can ensure that the vapor material or material particles emitted from the material source have high directionality during the thin film deposition process, convert the point source or line source in the device in various vapor deposition technologies such as vacuum thermal evaporation and molecular beam epitaxy into a surface source, eliminate the shadow effect, improve the uniformity of thin film deposition, and ultimately improve the product performance.

The disclosure can effectively avoid the mutual interference between the film forming process of pulse laser deposition and the film forming process of molecular beam epitaxy, and can prepare thin films with better quality that cannot be prepared in the related art.

The disclosure provides a thin film deposition apparatus, including:
a plurality of evaporation sources at a bottom of a film deposition chamber of the thin film deposition apparatus;
a plurality of beam splitters in a middle of the film deposition chamber, where each beam splitter comprises a frame and a plurality of beam splitter components arranged at intervals on the frame, and each beam splitter component comprises a plurality of reflecting surfaces connected in series; and
a plurality of plane reflectors corresponding one-to-one to the plurality of beam splitters, where each plane reflector is located at a side of a corresponding beam splitter inside the film deposition chamber.

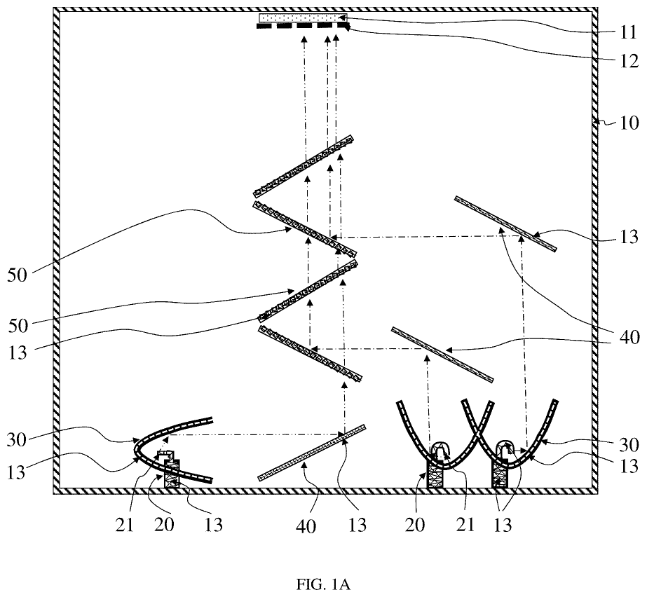

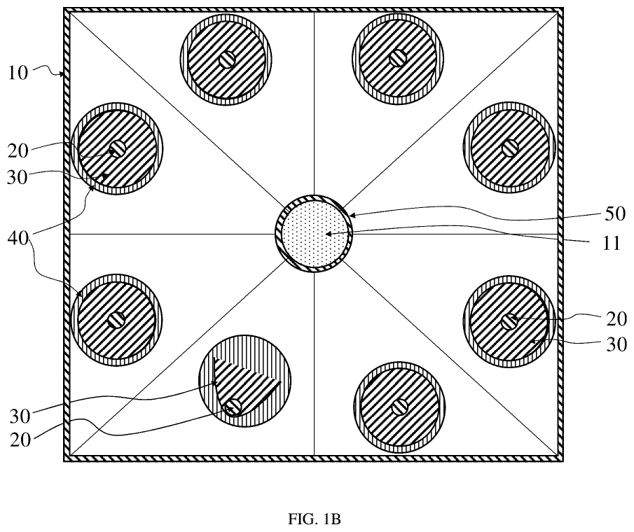

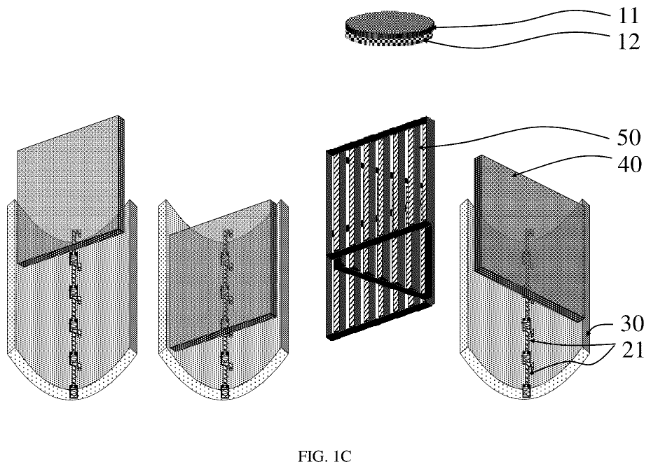

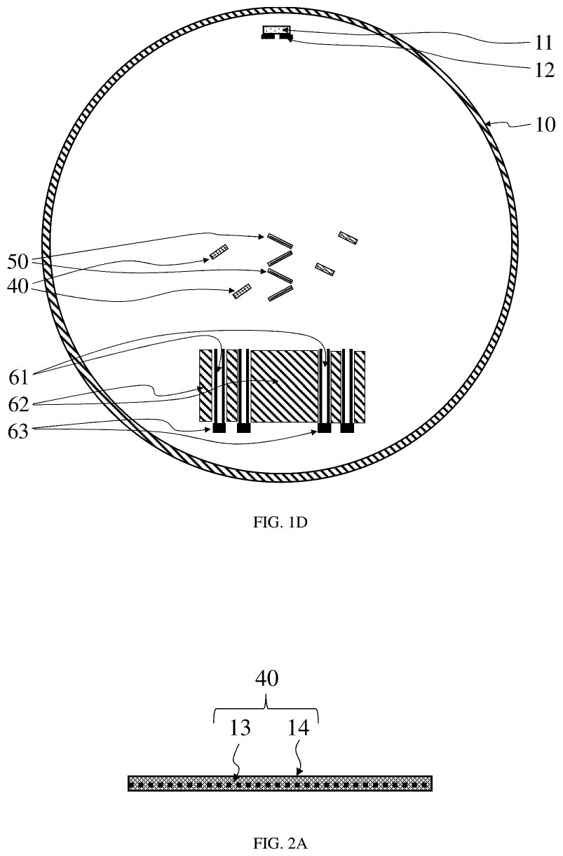

As shown in FIGS. 1A to 5, which shows schematic diagrams of (a part of) a thin film deposition apparatus. FIGS. 1A-1B show schematic diagrams of a thin film deposition apparatus with evaporation sources being point sources. FIGS. 1C shows a schematic diagram of a thin film deposition apparatus with evaporation sources being line sources. FIG. 1D shows a schematic diagram of a thin film deposition apparatus with evaporation sources being molecular beam sources, that is, a schematic diagram of a molecular beam epitaxy thin film deposition apparatus.

The thin film deposition apparatus with the evaporation sources being point sources is described as follows.

As shown in FIGS. 1A-1B, the thin film deposition apparatus with the evaporation sources being point sources includes film deposition chamber, where a plurality of evaporation sources 20 are arranged at a lower part of a film deposition chamber wall 10 (on a bottom wall), curved reflectors 30 are correspondingly arranged at a position of each evaporation source 20. A plurality of beam splitters 50 are arranged in a middle part of the film deposition chamber, and each beam splitter 50 includes a frame 51 and a plurality of beam splitter components 52 arranged at intervals on the frame 51. Each beam splitter component 52 includes a plurality of reflecting surfaces connected in series. A plane reflector 40 is correspondingly provided at a side of each beam splitter 50.

In some embodiments, in the thin film deposition apparatus with the evaporation sources being point sources, the plurality of point sources 20 correspond one-to-one to the plurality of curved reflectors 30 and the plurality of plane reflectors 40 respectively. Each curved reflector 30 can reflect a material beam from a corresponding evaporation source 20 to a corresponding plane reflector 40.

In some embodiments, the plane reflector 40 is set to be arranged at an acute angle with a horizontal direction. It should be noted that, the horizontal direction in the disclosure refers to a direction of a supporting surface for placing the thin film deposition apparatus. For example, the thin film deposition apparatus is placed on a level ground, then the direction of the level ground is the horizontal direction. A vertical direction is a direction perpendicular to the bottom wall of the thin film deposition apparatus, i.e., perpendicular to the horizontal direction.

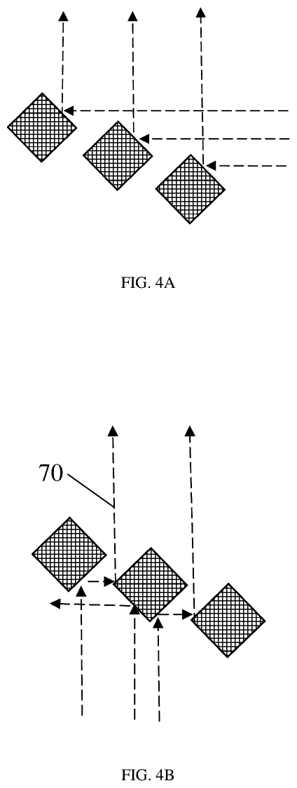

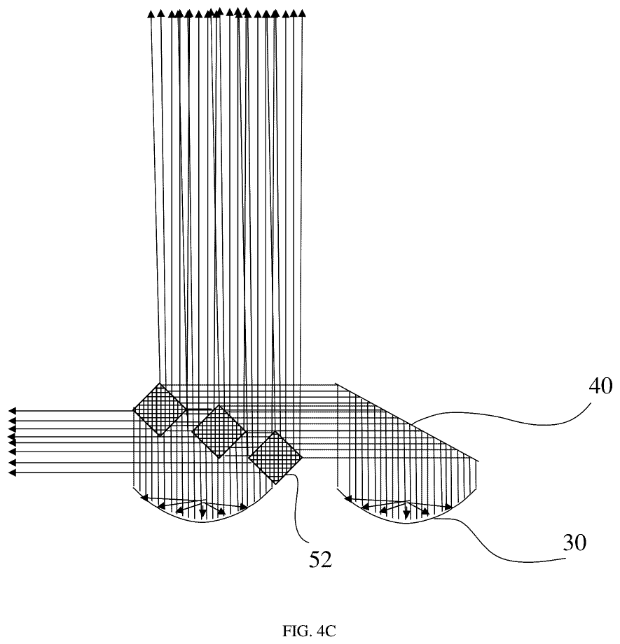

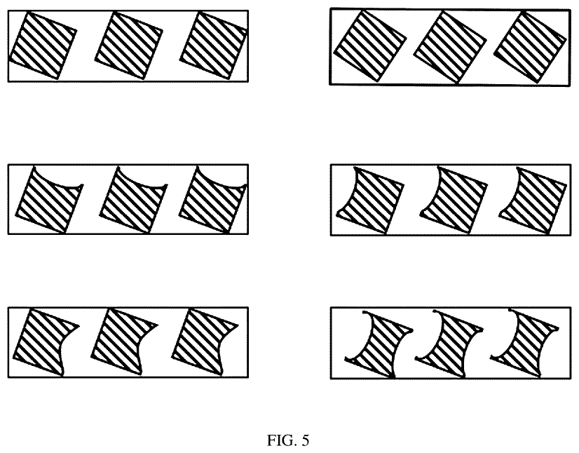

In some embodiments, as shown in FIGS. 4A-4C, any two adjacent reflecting surfaces among the plurality of reflecting surfaces connected in series are angled.

In some embodiments, the beam splitter component 52 has a square prism structure. As shown in FIGS. 4A-4C, a shape of a cross section of the beam splitter component 52 is a rhombus.

In some embodiments, each evaporation source 20 includes one nozzle 21, and the nozzle 21 faces a curved reflector 30 corresponding to the evaporation source 20. In practical implementation, the material beam is emitted from the nozzle 21 to the corresponding curved reflector 30.

In some embodiments, during the deposition process, a substrate 11 for film deposition is arranged at the top of the film deposition chamber. Each evaporation source 20 emits material beam 70 through the nozzle 21, each material beam 70 is emitted to the corresponding curved reflector 30, each material beam 70 is reflected to the corresponding plane reflector 40, and each plane reflector 40 then sprays the corresponding material beam 70 to the reflecting surfaces of the beam splitter components 52 of the corresponding beam splitter 50. All the material beams 70 are coated or doped on the substrate 11 after passing through the uppermost beam splitter 50 (the beam splitter 50 closest to the substrate). When the material beam 70 propagating in the vertical direction is sprayed to the corresponding reflecting surfaces of the beam splitter components 52 of the beam splitter 50, a part (about one half) of the material beam 70 are reflected in the horizontal direction onto a base of the wall, and a part (about the other half) of the material beam 70 continue to propagate in the vertical direction after being reflected. When the material beam 70 propagating in the horizontal direction is sprayed to the corresponding reflecting surfaces of the beam splitter components 52 of the corresponding beam splitter 50, the material beam 70 is totally reflected for further propagation in the vertical direction. The material beams 70 propagating in the vertical direction and the horizontal direction become mixed vertical material beams after being reflected by the beam splitter 50, and enter the uppermost beam splitter 50 (the beam splitter 50 closest to the substrate). The material beams 70 emitted from different evaporation sources 20 are coated or doped on the substrate 11 at a same small angle after passing through the uppermost beam splitter 50, and the deposition is completed after coating or doping. The thin film deposition apparatus and deposition method described in the disclosure are low in cost and convenient to use, and can ensure that the vapor material or material particles emitted from the material source have high directionality during the thin film deposition process, convert the point source or line source in the device in various vapor deposition technologies such as vacuum thermal evaporation and molecular beam epitaxy into a surface source, eliminate the shadow effect, improve the uniformity of deposition, and improve the product performance.

It should be noted that, in the embodiments of the disclosure, the method of placing the substrate 11 and the associated structures can refer to that in the related art, which is not limited here.

In some embodiments, a mask plate 12 can be further provided on a side of the substrate 11 facing the evaporation sources 20. In some embodiments, the substrate 11 is a silicon wafer, and a diameter of the corresponding mask plate 12 is larger than a diameter of the substrate 11. In the above structure, when deposition is performed, the entire deposition work is performed inside the film deposition chamber wall 10. The substrate 11 and the mask plate 12 are arranged at the upper part inside the film deposition chamber wall 10, and the material beams at the lower part are coated from top to bottom to complete the operation. For example, if the thin film to be deposited requires a specific pattern, the mask plate 12 with a specific pattern needs to be arranged at the thin film deposition side of the substrate 11, so that the deposition cannot be performed in the area of the substrate 11 blocked by the mask plate 12, while the deposition can be performed in the area hollowed out by the mask plate 12, thereby forming a pattern; if the deposited thin film has no patterning requirement, the mask plate can be removed.

In some embodiments, the plurality of beam splitters 50 are arranged end to end in the vertical direction. A plane of each beam splitter 50 and the horizontal direction are angled.

In some embodiments, in each beam splitter 50, the respective beam splitter components 52 all include a reflecting surface parallel to the plane reflector 40 corresponding to the beam splitter 50. As shown in FIG. 4C, the 3 beam splitter components shown in the figure all have a reflecting surface parallel to the right plane reflector 40.

In some embodiments, the frame of the beam splitter is oval in shape, as shown in FIG. 3B. It should be noted that, since a plane of the beam splitter and the horizontal direction are angled, in FIG. 1 which shows a top view of the thin film deposition apparatus, the beam splitter is shown as a rough circle.

In some embodiments, each plane reflector is rectangular in shape, and each curved reflector is paraboloid of revolution in shape.

In some embodiments, when the materials in the material evaporation source 20 are heated to an evaporation temperature, the materials are continuously sprayed from the nozzle 21 at a specific rate in the form of gas or nano-particle at various angles onto an inner surface of the corresponding curved reflector 30, become a nearly parallel material beam after being reflected by the parabolic surface of the curved reflector and are sprayed onto the surface of the plane reflector, and are then reflected by the plane reflector and sprayed onto the surface of the beam splitter. Finally, the material beams 70 emitted from different evaporation sources 20 are coated or doped on the substrate 11 at a same small angle after passing through the uppermost beam splitter 50, and the deposition is completed after coating or doping.

In some embodiments, there is a heating component 13 in each of the curved reflector 30, the plane reflector 40 and the beam splitter component 52.

In some embodiments, the heating component 13 is a resistance wire. In the above structure, the resistance wire is used for heating the corresponding structure, so that the curved reflector, the plane reflector and the beam splitter component all can be high-temperature structures, facilitating the reflection of the material beams.

In some embodiments, a surface material of the curved reflector 30 is stainless steel, Al₂O₃, single crystal silicon, or diamond coating film. A surface material of the plane reflector 40 is stainless steel, Al₂O₃, single crystal silicon, or diamond coating film. For example, the surfaces of the curved reflector 30 and the plane reflector 40 are single crystal silicon (100) surfaces with surface roughness less than 0.5 nm.

The thin film deposition apparatus with the evaporation sources being line sources is described as follows.

As shown in FIG. 1C, the thin film deposition apparatus with the evaporation sources being line sources includes film deposition chamber, where a plurality of evaporation sources 20 are arranged at a lower part of a film deposition chamber wall 10 (on a bottom wall), curved reflectors 30 are correspondingly arranged at a position of each evaporation source 20. A plurality of beam splitters 50 are arranged in a middle part of the film deposition chamber, and each beam splitter 50 includes a frame 51 and a plurality of beam splitter components 52 arranged at intervals on the frame 51. Each beam splitter component 52 includes a plurality of reflecting surfaces connected in series. A plane reflector 40 is correspondingly provided at a side of each beam splitter 50.

In some embodiments, in the thin film deposition apparatus with the evaporation sources being line sources, the plurality of line sources 20 correspond one-to-one to the plurality of curved reflectors 30 and the plurality of plane reflectors 40 respectively. Each curved reflector 30 can reflect a material beam from a corresponding evaporation source 20 to a corresponding plane reflector 40.

In some embodiments, the plane reflector 40 is set to be arranged at an acute angle with a horizontal direction.

In some embodiments, as shown in FIGS. 4A-4C, any two adjacent reflecting surfaces among the plurality of reflecting surfaces connected in series are angled.

In some embodiments, the beam splitter component 52 has a square prism structure. As shown in FIGS. 4A-4C, a shape of a cross section of the beam splitter component 52 is a rhombus.

In some embodiments, as shown in FIG. 1C, each evaporation source 20 includes a plurality of nozzles 21 arranged in a line, and each nozzle 21 faces a curved reflector 30 corresponding to the evaporation source 20.

In some embodiments, during the deposition process, a substrate 11 for film deposition is arranged at the top of the film deposition chamber. Each evaporation source 20 emits material beams 70 through the nozzles 21, each material beam 70 is emitted to the corresponding curved reflector 30, each material beam 70 is reflected to the corresponding plane reflector 40, and each plane reflector 40 then sprays the corresponding material beam 70 to the reflecting surfaces of the beam splitter components 52 of the corresponding beam splitter 50. All the material beams 70 are coated or doped on the substrate 11 after passing through the uppermost beam splitter 50 (the beam splitter 50 closest to the substrate). When the material beam 70 propagating in the vertical direction is sprayed to the corresponding reflecting surfaces of the beam splitter components 52 of the beam splitter 50, a part (about one half) of the material beam 70 are reflected in the horizontal direction onto a base of the wall, and a part (about the other half) of the material beam 70 continue to propagate in the vertical direction after being reflected. When the material beam 70 propagating in the horizontal direction is sprayed to the corresponding reflecting surfaces of the beam splitter components 52 of the corresponding beam splitter 50, the material beam 70 is totally reflected for further propagation in the vertical direction. The material beams 70 propagating in the vertical direction and the horizontal direction become mixed vertical material beams after being reflected by the beam splitter 50, and enter the uppermost beam splitter 50 (the beam splitter 50 closest to the substrate). The material beams 70 emitted from different evaporation sources 20 are coated or doped on the substrate 11 at a same small angle after passing through the uppermost beam splitter 50, and the deposition is completed after coating or doping.

It should be noted that, in the embodiments of the disclosure, the method of placing the substrate 11 and the associated structures can refer to that in the related art, which is not limited here.

In some embodiments, a mask plate 12 can be further provided on a side of the substrate 11 facing the evaporation sources 20. In some embodiments, the substrate 11 is a silicon wafer, and a diameter of the corresponding mask plate 12 is larger than a diameter of the substrate 11. In the above structure, when deposition is performed, the entire deposition work is performed inside the film deposition chamber wall 10. The substrate 11 and the mask plate 12 are arranged at the upper part inside the film deposition chamber wall 10, and the material beams at the lower part are coated from top to bottom to complete the operation. For example, if the thin film to be deposited requires a specific pattern, the mask plate 12 with a specific pattern needs to be arranged at the thin film deposition side of the substrate 11, so that the deposition cannot be performed in the area of the substrate 11 blocked by the mask plate 12, while the deposition can be performed in the area hollowed out by the mask plate 12, thereby forming a pattern; if the deposited thin film has no patterning requirement, the mask plate can be removed.

In some embodiments, the plurality of beam splitters 50 are arranged end to end in the vertical direction. A plane of each beam splitter 50 and the horizontal direction are angled.

In some embodiments, in each beam splitter 50, the respective beam splitter components 52 all include a reflecting surface parallel to the plane reflector 40 corresponding to the beam splitter 50. As shown in FIG. 4C, the 3 beam splitter components shown in the figure all have a reflecting surface parallel to the right plane reflector 40.

In some embodiments, the frame of the beam splitter is rectangular in shape, as shown in FIG. 1C. In this case, sizes of the beam splitter components in one beam splitter are same.

In some embodiments, each plane reflector is rectangular in shape, and each curved reflector is trough paraboloid in shape.

In some embodiments, when the materials in the material evaporation source 20 are heated to an evaporation temperature, the materials are continuously sprayed from the nozzles 21 at a specific rate in the form of gas or nano-particle at various angles onto an inner surface of the corresponding curved reflector 30, become a nearly parallel material beam after being reflected by the parabolic surface of the curved reflector and are sprayed onto the surface of the plane reflector, and are then reflected by the plane reflector and sprayed onto the surface of the beam splitter. Finally, the material beams 70 emitted from different evaporation sources 20 are coated or doped on the substrate 11 at a same small angle after passing through the uppermost beam splitter 50, and the deposition is completed after coating or doping.

In some embodiments, there is a heating component 13 in each of the curved reflector 30, the plane reflector 40 and the beam splitter component 52.

In some embodiments, the heating component 13 is a resistance wire. In the above structure, the resistance wire is used for heating the corresponding structure, so that the curved reflector, the plane reflector and the beam splitter component all can be high-temperature structures, facilitating the reflection of the material beams.

In some embodiments, a surface material of the curved reflector 30 is stainless steel, Al₂O₃, single crystal silicon, or diamond coating film. A surface material of the plane reflector 40 is stainless steel, Al₂O₃, single crystal silicon, or diamond coating film. For example, the surfaces of the curved reflector 30 and the plane reflector 40 are single crystal silicon (100) surfaces with surface roughness less than 0.5 nm.

The above structure provides an improved technical solution to address the deficiencies in the related art. The entire deposition apparatus includes a plurality of reflectors, beam splitters and other components, and the material beams emitted from one or more vapor material point sources or line sources can be uniformly mixed to form a surface source. This apparatus can be used to manufacture thin films or epitaxial devices with high uniformity and small shadow effect, improve the quality of the thin films, and reduce the effective sizes of the fine structures of the devices.

The thin film deposition apparatus with the evaporation sources being molecular beam sources is described as follows.

The structure including the beam splitters and the plane reflectors provided in the embodiments can be used for the molecular beam epitaxy thin film deposition apparatus. In this case, the evaporation sources are the molecular beam sources, which can be included in a molecular beam epitaxy device 60. In some embodiments, the molecular beam epitaxy device 60 can include a molecular beam emission slit 61, a liquid nitrogen cooling shield 62, and a source furnace flange 63. In practical implementations, the molecular beam emission slit 61 and the liquid nitrogen cooling shield 62 in combination can cause the emitted material beam to be nearly parallel. Thus, in the molecular beam epitaxy thin film deposition apparatus, the curved reflector is not required. The structures and functions of the plane reflectors and the beam splitters in the molecular beam epitaxy thin film deposition apparatus can refer to that in the above embodiments, which is not repeated here.

The disclosure further provides a method for using the thin film deposition apparatus according to the above embodiments, including:
emitting, by at least one evaporation source, a material beam, to enable the material beam to reach a plane reflector corresponding to the at least one evaporation source;
reflecting, by the plane reflector, the material beam to a beam splitter corresponding to the plane reflector; and
forming, by the plurality of beam splitters, the material beam from the at least one evaporation source as a planar material beam, to enable the planar material beam to reach a substrate at a top of the film deposition chamber.

In some embodiments, each evaporation source is correspondingly provided with a curved reflector, one curved reflector corresponds to one plane reflector and one beam splitter; and among the plurality of evaporation sources, an evaporation source corresponding to a beam splitter closest to the substrate is indicated as a first evaporation source, and remaining evaporation sources are indicated as second evaporation sources. The method includes:
S1, each second evaporation source emitting a material beam to a curved reflector corresponding to the second evaporation source, the curved reflector reflecting the material beam to a plane reflector corresponding to the curved reflector, and the plane reflector reflecting the material beam to corresponding reflecting surfaces of a plurality of beam splitter components of a beam splitter corresponding to the curved reflector;
S2, when a material beam propagating in a vertical direction reaches corresponding reflecting surfaces of a plurality of beam splitter components of a beam splitter corresponding to the curved reflector, a part of the material beam being reflected to a base on a wall of the film deposition chamber in a horizontal direction, and a part of the material beam being reflected by other reflecting surfaces for further propagation in the vertical direction;
S3, when a material beam propagating in the horizontal direction reaches corresponding reflecting surfaces of a plurality of beam splitter components of a beam splitter corresponding to the curved reflector, the material beam being totally reflected for further propagation in the vertical direction;
S4, the material beam for further propagation in the vertical direction in part or totally propagating to a next beam splitter until reaching corresponding reflecting surfaces of a plurality of beam splitter components of the beam splitter closest to substrate, a portion of the material beam being reflected to a base on the wall of the film deposition chamber in the horizontal direction, and a portion of the material beam being reflected by other reflecting surfaces for further propagation in the vertical direction until reaching the substrate;
S5, the first evaporation source emitting a material beam to a curved reflector corresponding to the first evaporation source, the curved reflector reflecting the material beam to a plane reflector corresponding to the curved reflector, the plane reflector reflecting the material beam in the horizontal direction onto corresponding reflecting surfaces of the plurality of beam splitter components of the beam splitter closest to the substrate, and the material beam being reflected to propagate in the vertical direction to reach the substrate.

The thin film deposition apparatus and deposition method described in the disclosure are low in cost and convenient to use, and can ensure that the vapor material or material particles emitted from the material source have high directionality during the thin film deposition process, convert the point source or line source in the device in various vapor deposition technologies such as vacuum thermal evaporation and molecular beam epitaxy into a surface source, eliminate the shadow effect, improve the uniformity of deposition, and improve the product performance.

The disclosure further provides a thin film deposition method, including:
S1: each evaporation source 20 emits a material beam 70 through a nozzle 21, where each material beam 70 is emitted to a corresponding curved reflector 30, each material beam 70 is reflected to a corresponding plane reflector 40, each plane reflector 40 then sprays the corresponding material beam 70 to a surface of a corresponding beam splitter component 52 of a beam splitter 50, and all the material beams 70 are coated or doped on a substrate 11 after passing through uppermost beam splitter 50;
S2: when material beams 70 propagating in a vertical direction are sprayed to surfaces of corresponding beam splitter components 52 of the beam splitter 50, a part (about one half) of the material beams 70 are reflected in a horizontal direction onto a base on the film deposition chamber wall, and a part (about the other half) of the material beams 70 continue to propagate after being reflected in the vertical direction;
S3: when material beams 70 propagating in the horizontal direction are sprayed to surfaces of corresponding beam splitter components 52 of the beam splitter 50, all the material beams 70 are reflected to propagate in the vertical direction;
S4: the material beams 70 propagating in the vertical direction and the horizontal direction become mixed vertical material beams after being reflected by the beam splitter 50, and enter the uppermost beam splitter 50; and
S5: material beams 70 emitted from different evaporation sources 20 are coated or doped on the substrate 11 at a same small angle after passing through the uppermost beam splitter 50, where deposition is completed after the coating or doping.

The technical problems, technical solutions and technical effects of the disclosure are further described as follows.

The technical problems addressed by the disclosure are as follows.

The material sources used in thin film vacuum vapor deposition technologies such as vacuum thermal evaporation and molecular beam epitaxy are generally point sources or line sources. The incident angles of the material beams emitted from these sources are generally not zero during the deposition onto the substrate, and the incident angles at different positions on the substrate are generally different, resulting in poor uniformity of the deposited thin film. The thin film devices also have larger effective sizes of fine structures due to the shadow effect. In the above technologies, it is difficult to uniformly mix materials emitted from different material sources.

The technical solution of the disclosure to solve the technical problems is as follows.

An evaporation source, a curved reflector, a plane reflector and a beam splitter all are provided with a heating component. The material beams emitted from different point-shaped material sources or line-shaped material sources are shaped into approximately parallel material beams through the curved reflector, or the molecular beam sources are used to directly emit the approximately parallel material beams; and then are emitted onto a series of beam splitters longitudinally arranged after the paths are changed by the plane reflector, and are mixed with the material beams emitted from the beam splitter in the previous stage, to jointly enter the beam splitter in the next stage in the longitudinal direction. Finally, these material beams are mixed together and incident onto the mask plate (if required) and substrate at a near zero angle, forming a device with a uniform and high-precision pattern.

In the embodiments with the evaporation sources being point sources or line sources, the nozzle of the evaporation source is a material beam shaping device. One end of the nozzle is connected to an outlet of the evaporation source (material source) to collect the material beams emitted from the material source. The material beams are reflected or secondary vapourized by the inner wall of the channel with a heating component arranged in the evaporation source, and enter a vacuum cavity formed by the coating cavity wall 10 from the narrow outlet at various angles.

In the embodiments with the evaporation sources being point sources or line sources, the curved reflector is a device having a heating component and a continuous smooth curved surface. The curved reflector is used to shape the material beams emitted from the nozzle into nearly parallel material beams through reflection. The surface shape of the curved reflector can be a curved surface formed by various curves such as circular arc, elliptical arc, parabola, cubic curve, etc. through rotation, translation and other operations. In some embodiments, the curved reflector used for the point source is a rotating parabolic reflector, and the curved reflector used for the line source is a trough parabolic reflector.

The plane reflector is a device having a heating component and a continuous smooth flat surface. A curved reflector can be considered a plane reflector if the surface curvature is relatively small. The plane reflector is used to change the propagation directions of the material beams, and can reflect the material beams emitted from different material sources to different beam splitters arranged in the same longitudinal direction.

The beam splitter is a device having a heating component and a discontinuous smooth surface, and includes a plurality of reflectors with multi-directional reflecting surfaces. When the material beams that are incident from different directions strike different reflecting surfaces of the beam splitter, the material beams are reflected or secondary vapourized by the discontinuous surfaces of the beam splitter and finally emitted out in the same direction. In order to deposit multiple layers of different materials or simultaneously deposit multiple different materials on the substrate, it is usually necessary to arrange a plurality of beam splitters at one side of the substrate for thin film deposition and in a direction perpendicular to the substrate. Here, the direction perpendicular to the substrate is defined as the longitudinal direction, and the direction parallel to the substrate is defined as the lateral direction.

The surface material of the reflecting surfaces of the curved reflector, the plane reflector and the reflecting surfaces of the beam splitter component is a composite material of one or more of metal, inorganic non-metal material and polymer. In some embodiments, the surface material of the reflecting surfaces of the reflector and the beam splitter component is stainless steel, Al₂O₃, single crystal silicon, diamond coating film, etc.

The evaporation temperature of the material i of the material beam is set to Ct(i), and the surface adsorption energy of the material i of the material beam on the material j of the reflecting surface at absolute zero is set to E_{ab}(i, j).

The heating component (heating source) is generally an electric heating wire. When the heating temperature is greater than Ct(i)+E_{ab}(i, j)/k_{B}, the material beam i is mainly reflected on the surface j of the reflector or beam splitter component; when the heating temperature is lower than that temperature but greater than Ct(i), the material beam i is reflected and secondary vapourized on the surface j of the reflector or beam splitter component; when the heating temperature is lower than Ct(i), the material i is mainly deposited. Here, KB is the Boltzmann constant.

The incident angle of the material beam shaped by the reflectors and beam splitter on the substrate depends on the surface material, roughness, temperature, surface shape of the reflector and beam splitter, and the size of the nozzle outlet for the material beam. The smaller the surface roughness of the reflector and beam splitter, the higher the temperature, the greater the curvature, and the smaller (point source) or narrower (line source) the nozzle outlet, the smaller the incident angle. FIG. 5 is a schematic diagram showing some optional cross-sectional shapes of the beam splitter and reflector, where the curved shapes and orientation angles of the reflecting surfaces are different.

The technical effect of the disclosure lies in that a coating film with high uniformity and high-fine structure can be obtained.

In order to further understand the purposes, structures, features and functions of the disclosure, the detailed description in cooperation with embodiments are as follows.

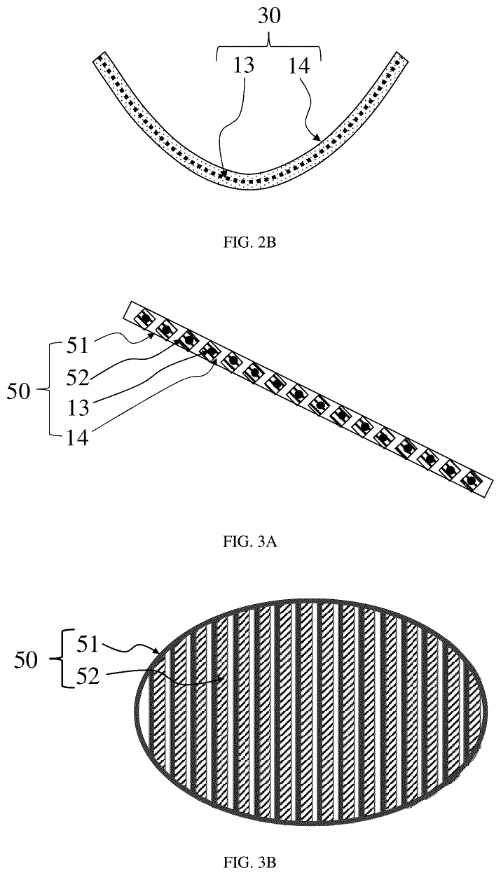

Regarding the thin film deposition apparatus (film coating apparatus of vacuum thermal evaporation with point sources), FIGS. 1A and 1B are respectively a side view and a top view of a simplified schematic diagram of the film coating apparatus of vacuum thermal evaporation with point sources. In the drawings, reference sign 10 indicates a film deposition chamber wall, reference sign 11 indicates a film coating substrate, reference sign 12 indicates a film coating mask plate, reference sign 13 indicates a heating apparatus, reference sign 14 indicates a reflecting surface, reference sign 20 indicates an evaporation source, reference sign 21 indicates a nozzle, reference sign 30 indicates a curved reflector, reference sign 40 indicates a plane reflector, and reference sign 50 indicates a beam splitter. Here, the structures of the curved reflector 30, plane reflector 40 and beam splitter 50 are shown respectively in FIGS. 2A, 2B, 3A and 3B.

Here, in an example embodiment, the film coating substrate 11 is a silicon wafer with a diameter of 300 mm; the diameter of the mask plate 12 is 320 mm, the thickness of the mask plate 12 is 5 μm, and the pattern opening size of the mask plate 12 is 5 μm; all reflector surfaces are single crystal silicon (100) surfaces with surface roughness less than 0.5 nm; the heating component is a resistance wire, and the temperature of the resistance wire needs to be adjusted according to the evaporation temperatures and evaporation rates of different materials and the reflection angle of the reflector; the orthographic projections of the curved reflector, plane reflector and beam splitter in the lateral direction or longitudinal direction are 330 mm; and each reflector in the beam splitter is a square prism with a side length of 1 mm, and the beam splitter is installed at an elevation angle of 26.5° relative to the lateral direction.

In FIG. 1A, if the thin film to be deposited has a specific pattern, the mask plate with a specific pattern needs to be installed on the thin film deposition side of the substrate, so that the thin film cannot be deposited in the area of the substrate blocked by the mask plate, while the thin film can be deposited in the area hollowed out by the mask plate; if the deposited thin film has no patterning requirement, the mask plate can be removed.

The dotted lines in FIG. 1A indicate propagation paths of the material beams in the reflector and beam splitter. When the materials in the material evaporation source are heated to the evaporation temperature, the materials are continuously sprayed from the nozzle at a specific rate in the form of gas or nano-particle at various angles onto the inner surface of the parabolic reflector, become the nearly parallel material beams after being reflected by the high-temperature parabolic surface and are sprayed onto the surface of the plane reflector, and are then deflected by the plane reflector and sprayed onto the surface of the beam splitter.

FIGS. 3A and 3B are structural schematic diagrams of the beam splitter. FIG. 3A is a side view of the beam splitter when installed at a specific angle in the device. In FIG. 3A, reference sign 51 indicates a beam splitter frame, reference sign 52 indicates a beam splitter component (beam splitter reflector), reference sign 13 indicates a heating component (heating device), and reference sign 14 indicates a reflecting surface. FIG. 3B is a schematic top-view of the beam splitter.

When the material beams propagating longitudinally are sprayed onto the surface of the beam splitter, about one half of the material beams will be reflected laterally onto the base of the wall, and the other half of the material beams will continue to propagate longitudinally after being reflected twice, as shown in FIG. 4B; when the material beams propagating laterally are sprayed onto the surface of the beam splitter, all the material beams will be reflected to propagate in the longitudinal direction, as shown in FIG. 4A; and at this point, the material beams propagating laterally and longitudinally become mixed longitudinal material beams after being reflected by the beam splitter, and enter the beam splitter in the next stage, as shown in FIG. 4C.

FIG. 1C is a schematic diagram of a film coating apparatus (deposition apparatus) with a line source (a perspective diagram viewed from a 45° downward angle). The working principle thereof is the same as that of the film coating apparatus of vacuum thermal evaporation using the point source, except that the shapes of the reflector and beam splitter are different. Here, the plane reflector is rectangular in shape, the curved reflector is a trough paraboloid in shape, and the beam splitter is a rectangular device including square prisms with the same length.

Regarding the film coating apparatus of molecular beam epitaxy, FIG. 1D can be referenced. A simplified schematic diagram (side view) of the structure of the film coating apparatus of molecular beam epitaxy is shown in FIG. 1D. Here, reference sign 61 indicates a molecular beam emission slit, reference sign 62 indicates a liquid nitrogen cooling shield, and reference sign 63 indicates a source furnace flange. The material beams emitted from the flange pass through the emission slit and then enter the substrate and the mask plate at almost the same angle. Through the reflection mixing of the plane reflector 40 and the beam splitter 50, the molecular beams emitted from different material sources are coated or doped on the substrate at the same small angle, thereby completing the film coating of the substrate.

According to the thin film deposition apparatus and deposition method described in the disclosure, a plurality of reflectors, beam splitters and other components are included. The material beams emitted from one or more vapor material point sources, line sources or molecular beam sources can be uniformly mixed and shaped to form a surface source. The apparatus can be used to manufacture thin films or epitaxial devices with high uniformity and small shadow effect, improve the quality of the thin films, and reduce the effective sizes of the fine structures of the devices. During the deposition process, taking the thin film deposition apparatus using the point sources or the line sources, each evaporation source 20 emits material beam 70 through the nozzle 21, each material beam 70 is emitted to the corresponding curved reflector 30, each material beam 70 is reflected to the corresponding plane reflector 40, each plane reflector 40 then sprays the corresponding material beam 70 to the surface of the corresponding beam splitter component 52 of the beam splitter 50, and all the material beams 70 are coated or doped on the substrate 11 after passing through the uppermost beam splitter 50; when the material beams 70 propagating in the vertical direction are sprayed to the surfaces of the corresponding beam splitter components 52 of the beam splitter 50, a part (about one half) of the material beams 70 are reflected in the horizontal direction onto the base of the wall, and a part (about the other half) of the material beams 70 continue to propagate after being reflected in the vertical direction; when the material beams 70 propagating in the horizontal direction are sprayed to the surfaces of the corresponding beam splitter components 52 of the beam splitter 50, all the material beams 70 are reflected to propagate in the vertical direction; the material beams 70 propagating in the vertical direction and the horizontal direction become mixed vertical material beams after being reflected by the beam splitter 50, and enter the uppermost beam splitter 50; and the material beams 70 emitted from different evaporation sources 20 are coated or doped on the substrate 11 at the same small angle after passing through the uppermost beam splitter 50, and then the deposition is completed.

The disclosure is exemplarily described above in conjunction with the accompanying drawings. Obviously, the specific implementation of the disclosure is not limited to the above-mentioned manner. As long as various improvements are made using the method concept and technical solution of the disclosure, or the concept and technical solution of the disclosure are directly applied to other occasions without improvement, they are all within the protection scope of the disclosure.

What is claimed is:

1. A thin film deposition apparatus, comprising:
a plurality of evaporation sources at a bottom of a film deposition chamber of the thin film deposition apparatus;
a plurality of beam splitters in a middle of the film deposition chamber, wherein each beam splitter comprises a frame and a plurality of beam splitter components arranged at intervals on the frame, and each beam splitter component comprises a plurality of reflecting surfaces connected in series; and
a plurality of plane reflectors corresponding one-to-one to the plurality of beam splitters, wherein each plane reflector is located at a side of a corresponding beam splitter inside the film deposition chamber.

2. The thin film deposition apparatus according to claim 1, wherein the reflecting surface is flat or curved.

3. The thin film deposition apparatus according to claim 2, wherein any two adjacent reflecting surfaces among the plurality of reflecting surfaces connected in series are angled.

4. The thin film deposition apparatus according to claim 3, wherein the beam splitter component has a square prism structure.

5. The thin film deposition apparatus according to claim 3, further comprising a plurality of curved reflectors, corresponding one-to-one to the plurality of evaporation sources, at the bottom of the film deposition chamber;
wherein the plurality of curved reflectors correspond one-to-one to the plurality of plane reflectors respectively, and each curved reflector is configured to reflect a material beam from a corresponding evaporation source onto a corresponding plane reflector.

6. The thin film deposition apparatus according to claim 5, wherein each evaporation source comprises at least one nozzle, and the at least one nozzle faces a curved reflector corresponding to the evaporation source.

7. The thin film deposition apparatus according to claim 6, wherein each plane reflector is rectangular in shape, and each curved reflector is paraboloid of revolution or trough paraboloid in shape.

8. The thin film deposition apparatus according to claim 5, wherein each evaporation source is a point source, and the frame of the beam splitter is oval in shape.

9. The thin film deposition apparatus according to claim 5, wherein each evaporation source is a line source, and the frame of the beam splitter is rectangular in shape.

10. The thin film deposition apparatus according to claim 5, wherein a surface material of the curved reflector is stainless steel, Al₂O₃, single crystal silicon, or diamond coating film; and
a surface material of the plane reflector is stainless steel, Al₂O₃, single crystal silicon, or diamond coating film.

11. The thin film deposition apparatus according to claim 5, wherein the plane reflector comprises a heating component inside the plane reflector;
the beam splitter component comprises a heating component inside the beam splitter component; and
the curved reflector comprises a heating component inside the curved reflector.

12. The thin film deposition apparatus according to claim 11, wherein the heating component is a resistance wire.

13. The thin film deposition apparatus according to claim 1, wherein the plane reflector comprises a heating component inside the plane reflector; and
the beam splitter component comprises a heating component inside the beam splitter component.

14. The thin film deposition apparatus according to claim 13, wherein the heating component is a resistance wire.

15. The thin film deposition apparatus according to claim 1, wherein a surface material of the plane reflector is stainless steel, Al₂O₃, single crystal silicon, or diamond coating film.

16. The thin film deposition apparatus according to claim 1, wherein in each beam splitter, each beam splitter component comprises a reflecting surface parallel to a plane reflector corresponding to the beam splitter.

17. The thin film deposition apparatus according to claim 1, wherein each evaporation source is a molecular beam source.

18. The thin film deposition apparatus according to claim 1, wherein the plurality of beam splitters are arranged along a direction perpendicular to a bottom wall of the film deposition chamber.

19. A method for using the thin film deposition apparatus according to claim 1, comprising:
emitting, by at least one evaporation source, a material beam, to enable the material beam to reach a plane reflector corresponding to the at least one evaporation source;
reflecting, by the plane reflector, the material beam to a beam splitter corresponding to the plane reflector; and
forming, by the plurality of beam splitters, the material beam from the at least one evaporation source as a planar material beam, to enable the planar material beam to reach a substrate at a top of the film deposition chamber.

20. The method according to claim 19, wherein each evaporation source is correspondingly provided with a curved reflector, one curved reflector corresponds to one plane reflector and one beam splitter; and among the plurality of evaporation sources, an evaporation source corresponding to a beam splitter closest to the substrate is indicated as a first evaporation source, and remaining evaporation sources are indicated as second evaporation sources; the method comprises:
S1, each second evaporation source emitting a material beam to a curved reflector corresponding to the second evaporation source, the curved reflector reflecting the material beam to a plane reflector corresponding to the curved reflector, and the plane reflector reflecting the material beam to corresponding reflecting surfaces of a plurality of beam splitter components of a beam splitter corresponding to the curved reflector;
S2, when a material beam propagating in a vertical direction reaches corresponding reflecting surfaces of a plurality of beam splitter components of a beam splitter corresponding to the curved reflector, a part of the material beam being reflected to a base on a wall of the film deposition chamber in a horizontal direction, and a part of the material beam being reflected by other reflecting surfaces for further propagation in the vertical direction;
S3, when a material beam propagating in the horizontal direction reaches corresponding reflecting surfaces of a plurality of beam splitter components of a beam splitter corresponding to the curved reflector, the material beam being totally reflected for further propagation in the vertical direction;
S4, the material beam for further propagation in the vertical direction in part or totally propagating to a next beam splitter until reaching corresponding reflecting surfaces of a plurality of beam splitter components of the beam splitter closest to substrate, a portion of the material beam being reflected to a base on the wall of the film deposition chamber in the horizontal direction, and a portion of the material beam being reflected by other reflecting surfaces for further propagation in the vertical direction until reaching the substrate;
S5, the first evaporation source emitting a material beam to a curved reflector corresponding to the first evaporation source, the curved reflector reflecting the material beam to a plane reflector corresponding to the curved reflector, the plane reflector reflecting the material beam in the horizontal direction onto corresponding reflecting surfaces of the plurality of beam splitter components of the beam splitter closest to the substrate, and the material beam being reflected to propagate in the vertical direction to reach the substrate.
